(19) United States
(12) Patent Application Publication
(10) Pub. No.: US 2026/0113848 A1
(43) Pub. Date: Apr. 23, 2026

(54) COMPACT POWER MODULES

(71) Applicant: Analog Devices International Unlimited Company, Co. Limerick (IE)

(72) Inventors: Teik Tiong TOONG, Georgetown (MY); Muhammad Syahmie CHE SULIMAN, Sungai Jawi (MY)

(21) Appl. No.: 18/922,856

(22) Filed: Oct. 22, 2024

(51) Int. Cl. H05K 1/18; H05K 1/14

(52) U.S. Cl. CPC H05K 1/181; H05K 1/14; H05K 2201/1003; H05K 2201/10166

(57) ABSTRACT

Compact power modules are disclosed herein. In certain embodiments, a power module includes a main circuit board, an inductor component attached to the main circuit board and including two or more inductors formed in a dielectric body, and two or more power regulation circuit boards attached to different sides of the inductor component. Each power regulation circuit board includes a semiconductor die for regulating a current through a corresponding inductor of the inductor component.

### FIELD OF THE DISCLOSURE

Embodiments of the invention relate to electronic systems, and more particularly, to power modules for providing power regulation.

### BACKGROUND

A power module can include one or more switching regulators that operate in combination with one or more inductors to provide power regulation. For example, the switching regulator can employ switches (for instance, power transistors) coupled in series and/or parallel with an output terminal that provides an output voltage to a load through an inductor. Additionally, a controller turns the switches ON and OFF to control delivery of current pulses to the output terminal through the inductor, which converts the switched pulses into a steady load current.

A power module can include a semiconductor die on which metal-oxide-semiconductor field-effect transistors (MOSFET) and a driver are formed. Such a semiconductor die is referred to as a driver and MOSFET (DrMOS) die or integrated circuit (IC).

### SUMMARY OF THE DISCLOSURE

Compact power modules are disclosed herein. In certain embodiments, a power module includes a main circuit board, an inductor component attached to the main circuit board and including two or more inductors formed in a dielectric body, and two or more power regulation circuit boards attached to different sides of the inductor component. Each power regulation circuit board includes a semiconductor die for regulating a current through a corresponding inductor of the inductor component.

By implementing the power regulation circuit boards in this manner, a compact power module for multi-phase power regulation is achieved. Further, the number of power regulation circuit boards attached to the inductor component and the corresponding number of inductors can be selected to provide a desired number of phases for power regulation.

In one aspect, a power module includes a main circuit board and an inductor component attached to the main circuit board. The inductor component includes two or more inductors formed in a dielectric body. The power module further includes two or more power regulation circuit boards each attached to a different side of the inductor component. Each power regulation circuit board includes a semiconductor die operable to regulate a current through a corresponding inductor of the two or more inductors.

In another aspect, a power regulation system includes a customer circuit board and a first power module attached to the customer circuit board. The first power module includes a main circuit board and an inductor component attached to the main circuit board. The inductor component includes two or more inductors formed in a dielectric body. The first power module further includes two or more power regulation circuit boards each attached to a different side of the inductor component. Each power regulation circuit board includes a semiconductor die operable to regulate a current through a corresponding inductor of the two or more inductors.

In another aspect, a method of power module assembly is provided. The method includes attaching a first power regulation circuit board to a first side of an inductor component, the inductor component including a first inductor and a second inductor formed in a dielectric body. The method further includes electrically connecting a first semiconductor die on the first power regulation circuit board to the first inductor. The method further includes attaching a second power regulation circuit board to a second side of the inductor component, electrically connecting a second semiconductor die on the second power regulation circuit board to the second inductor, and attaching the inductor component including the first power regulation circuit board and the second power regulation circuit board to a main circuit board to form a power module.

### BRIEF DESCRIPTION OF THE DRAWINGS

FIG. 1A is a front perspective view of a power module according to one embodiment.

FIG. 1B is a plan view of the power module of FIG. 1A.

FIG. 1C is a left side view of the power module of FIG. 1A.

FIG. 1D is a front view of the power module of FIG. 1A.

FIG. 2A is a first portion of a method of assembling the power module of FIGS. 1A-1D according to one embodiment.

FIG. 2B is a second portion of a method of assembling the power module of FIGS. 1A-1D according to one embodiment.

FIG. 2C is a third portion of a method of assembling the power module of FIGS. 1A-1D according to one embodiment.

FIG. 3A is a front perspective view of a power module according to another embodiment.

FIG. 3B is a plan view of the power module of FIG. 3A.

FIG. 3C is a front view of the power module of FIG. 3A.

FIG. 3D is a left side view of the power module of FIG. 3A.

FIG. 4A is a first portion of a method of assembling the power module of FIGS. 3A-3D according to one embodiment.

FIG. 4B is a second portion of a method of assembling the power module of FIGS. 3A-3D according to one embodiment.

FIG. 4C is a third portion of a method of assembling the power module of FIGS. 3A-3D according to one embodiment.

FIG. 4D is a fourth portion of a method of assembling the power module of FIGS. 3A-3D according to one embodiment.

FIG. 4E is a fifth portion of a method of assembling the power module of FIGS. 3A-3D according to one embodiment.

FIG. 5A is a front perspective view of a power module according to another embodiment.

FIG. 5B is a plan view of the power module of FIG. 5A.

FIG. 5C is a front view of the power module of FIG. 5A.

FIG. 5D is a rear view of the power module of FIG. 5A.

FIG. 5E is a rear perspective view of the power module of FIG. 5A.

FIG. 5F is a cross-section of the power module of FIG. 5A taken along the line 5F-5F.

FIG. 5G is a perspective view of an inner side of a power regulation circuit board of the power module of FIG. 5A.

FIG. 5H is a perspective view of an inductor component of the power module of FIG. 5A.

FIG. 6A is a first portion of a method of assembling the power module of FIGS. 5A-5F according to one embodiment.

FIG. 6B is a second portion of a method of assembling the power module of FIGS. 5A-5F according to one embodiment.

FIG. 6C is a third portion of a method of assembling the power module of FIGS. 5A-5F according to one embodiment.

FIG. 6D is a fourth portion of a method of assembling the power module of FIGS. 5A-5F according to one embodiment.

FIG. 6E is a fifth portion of a method of assembling the power module of FIGS. 5A-5F according to one embodiment.

FIG. 7 is a plan view of a power regulation system according to one embodiment.

FIG. 8 is a circuit diagram of a power module according to one embodiment.

### DETAILED DESCRIPTION OF EMBODIMENTS

The following detailed description of embodiments presents various descriptions of specific embodiments of the invention. However, the invention can be embodied in a multitude of different ways. In this description, reference is made to the drawings where like reference numerals may indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Conventional power modules have a large footprint, particularly for power modules implemented for multi-phase power regulation. For example, a power module can include two or more DrMOS dies placed side by side on a circuit board. However, such a power module can have a large footprint, high parasitic resistance, and/or poor thermal performance.

Compact power modules are disclosed herein. In certain embodiments, a power module includes a main circuit board, an inductor component attached to the main circuit board and including two or more inductors formed in a dielectric body, and two or more power regulation circuit boards attached to different sides of the inductor component. Each power regulation circuit board includes a semiconductor die, such as a DrMOS die, for regulating a current through a corresponding inductor of the inductor component.

The number of power regulation circuit boards attached to the inductor component and the corresponding number of inductors can be selected to provide a desired number of phases for power regulation. In a first example, two power regulation circuit boards are attached to opposite sides of the inductor component to provide a two-phase (2-phase) power module. In a second example, four power regulation circuit boards are attached to different sides of the inductor component to provide a four-phase (4-phase) power module.

In certain implementations, the power regulation circuit boards are attached at an angle of about 90° (for instance, within 80° to 100°) relative to a surface of the main circuit board.

By implementing the power regulation circuit boards to be substantially perpendicular to the main circuit board, a compact power module for multi-phase power regulation is achieved. For example, the teachings herein can be used to achieve a 4-phase power module in a footprint of 8 mm×8 mm or smaller.

In certain implementations, multiple power modules are arrayed to provide additional phases for a power regulation system. For example, two or more 4-phase power modules can be arrayed on a customer circuit board to provide 8 or more phases for power regulation.

The inductor component can include a dielectric body (for example, a ferrite core) and two or more inductors (for instance, copper windings) that extend through the dielectric body. In certain implementations, one end of each inductor is electrically connected to a corresponding output of a DrMOS die (for example, an output of a switching regulator) while a second end of the inductor is electrically connected to a corresponding terminal on the main circuit board. The main circuit board in turn can be attached to a customer circuit board.

In addition to including one or more semiconductor dies (for instance, a DrMOS die), the power regulation circuit boards can include various components (including, but not limited to, capacitors) attached to the power regulation circuit board using surface mount technology (SMT). In one example, surface mount components are included on a side of the power regulation circuit board that includes the DrMOS die. In a second example, the surface mount components and the DrMOS die are included on opposite sides of the regulation circuit board. For instance, a recess can be formed in the dielectric body of the inductor component to provide clearance for the surface mount components.

In certain implementations, a DrMOS die is packaged (for instance, in a quad flat no-lead (QFN) package, a land grid array (LGA) package, or other suitable package) and attached to the power regulation circuit board. However, other implementations are possible, such as configurations in which the DrMOS die is attached by a flip-chip process to the power regulation circuit board and encapsulated using a mold compound. In such implementations, grinding can be performed on a back side of the encapsulation to expose a portion of each DrMOS die for improved thermal performance.

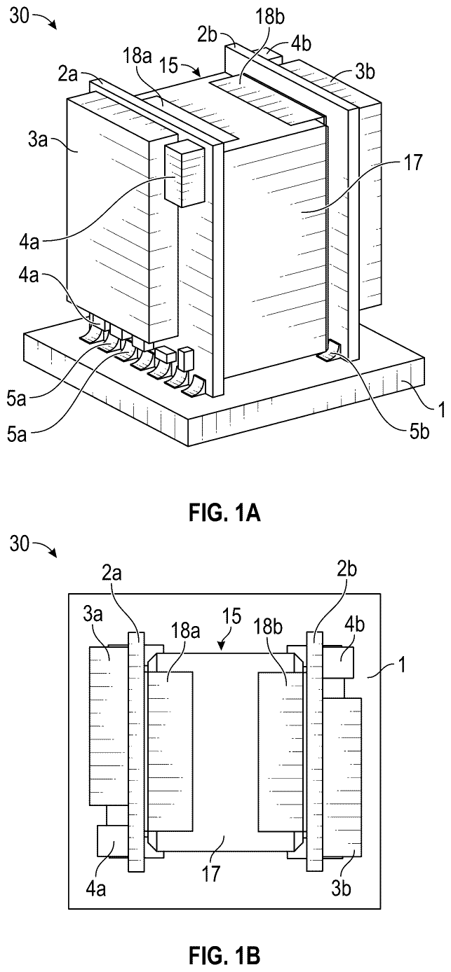

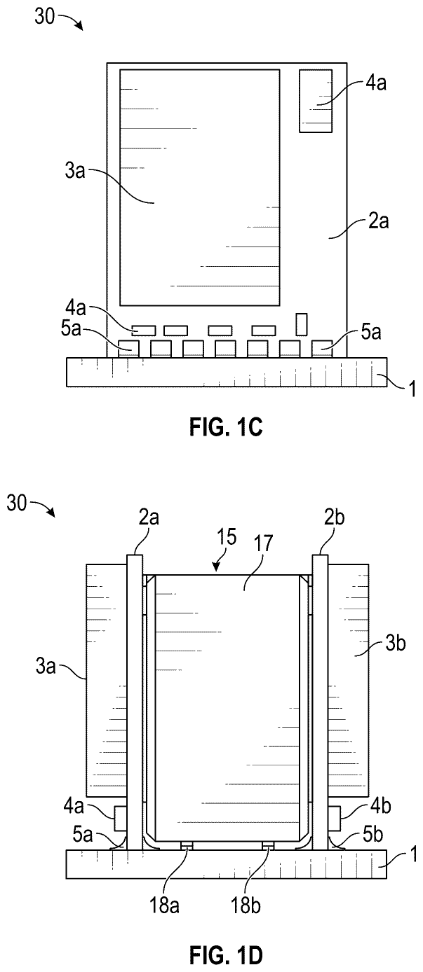

FIG. 1A is a front perspective view of a power module 30 according to one embodiment. FIG. 1B is a plan view of the power module 30 of FIG. 1A. FIG. 1C is a left side view of the power module 30 of FIG. 1A. FIG. 1D is a front view of the power module 30 of FIG. 1A.

With reference to FIGS. 1A-1D, the power module 30 includes a main circuit board 1, an inductor component 15, a first power regulation circuit board 2a, and a second power regulation circuit board 2b.

In the illustrated embodiment, a bottom surface of the inductor component 15 is attached to a top surface of the main circuit board 1. Additionally, the first power regulation circuit board 2a is attached to a first side surface of the inductor component 15, while the second power regulation circuit board 2b is attached to a second side surface of the inductor component 15 opposite the first side surface. The inductor component 15 includes a dielectric body 17 (for example, a ferrite core), a first inductor 18a through the dielectric body 17, and a second inductor 18b through the dielectric body 17. In certain implementations, the first inductor 18a and the second inductor 18b correspond to copper windings formed through the dielectric body 17.

Although the power module 30 depicts an example of a two-phase power module, the teachings herein are applicable to power modules with a different number of phases.

Each of the power regulation circuit boards 2a/2b includes a DrMOS die and various surface mount components attached to a side of the circuit board opposite the inductor component 15. For example, the DrMOS die 3a and components 4a are attached to the first power regulation circuit board 2a, while the DrMOS die 3b and components 4b are attached to the second power regulation circuit board 2b. The components 4a/4b can include capacitors and/or other passive and/or active components desired for a particular application.

The DrMOS dies 3a/3b serve to regulate a current through a corresponding inductor of the inductor component 15. For example, an output of the first DrMOS die 3a is electrically connected to a first end of first inductor 18a near the top surface of the inductor component 15, while as shown in FIG. 1D a second end of the first inductor 18a near the bottom surface of the inductor component 15 is electrically connected to a corresponding terminal of the main circuit board 1. Additionally, an output of the second DrMOS die 3b is electrically connected to a first end of second inductor 18b near the top surface of the inductor component 15, while a second end of the second inductor 18b near the bottom surface of the inductor component 15 is electrically connected to a corresponding terminal of the main circuit board 1.

In the illustrated embodiment, the DrMOS dies 3a/3b are packaged (for instance, in a QFN package or LGA package) and thereafter attached to a corresponding power regulation circuit board. However, other implementations are possible, such as configurations in which the DrMOS die is mounted to the power regulation circuit board (for example, using a flip-chip attachment) and encapsulated using a mold compound.

With continuing reference to FIGS. 1A-1D, a bottom edge of the first power regulation circuit board 2a and a bottom edge of the second power regulation circuit board 2b each attach to the main circuit board 1. Additionally, the main circuit board 1 includes first electrical connectors 5a for providing electrical connections to the first power regulation circuit board 2a and second electrical connectors 5b for providing electrical connections to the second power regulation circuit board 2b. The electrical connectors 5a/5b can carry power, ground, signals, and/or provide any other desired electrical connectivity. In certain implementations, the electrical connectors 5a/5b solder to corresponding conductors of the power regulation circuit boards 2a/2b.

The main circuit board 1 can attach to a customer circuit board (not shown in FIGS. 1A-1D) to provide electrical connections to a larger electronic system.

In the illustrated embodiment, the power regulation circuit boards 2a/2b are attached at an angle of about 90° relative to the top surface of the main circuit board 1. By implementing the power regulation circuit boards 2a/2b in this manner, a compact form factor is achieved. For example, in some implementations, the power module 30 occupies a footprint of 8 mm×8 mm or smaller and can have a height of less than 9 mm. Implementing the power module 30 in this manner can provide not only a compact form factor, but also reduced parasitic resistance and/or improved thermal performance.

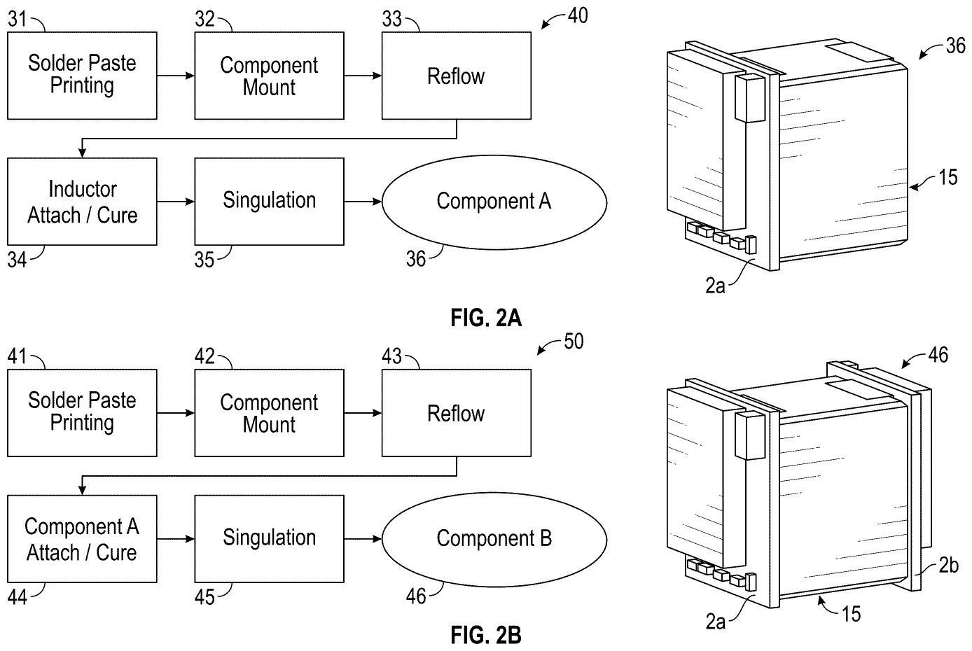

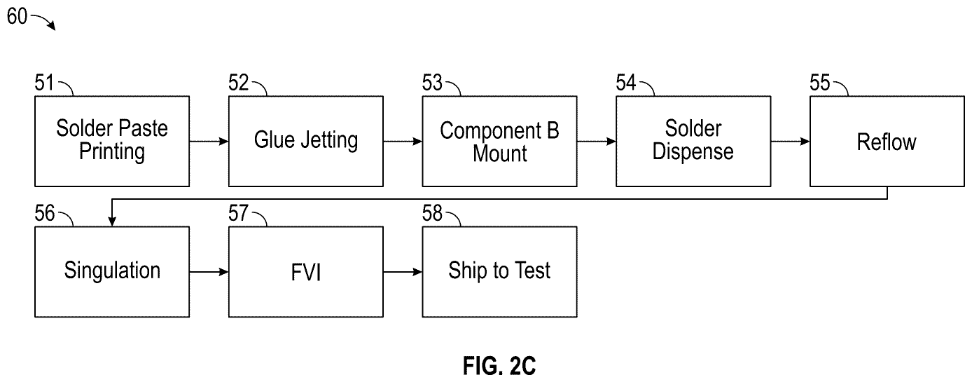

FIG. 2A is a first portion 40 of a method of assembling the power module 30 of FIGS. 1A-1D according to one embodiment. Additionally, FIG. 2B depicts a second portion 50 of the method, while FIG. 2C depicts a third portion 60 of the method.

Although one embodiment of assembling the power module 30 is shown, the power module 30 can be assembled in other ways. Accordingly, other implementations are possible.

With reference to FIGS. 2A-2C, the method begins by solder paste printing 31 the first power regulation circuit board 2a. For example, screen printing can be used to apply a solder paste to solder pads of the first power regulation circuit board 2a. Thereafter, a component mount 32 is performed to mount the first power regulation circuit board 2a on a first side of the inductor component 15. A reflow 33 and an inductor attach cure 34 is performed to secure the first power regulation circuit board 2a to the inductor component 15. For example, the reflow 33 can include a controlled heat process such that the solder paste reflows in a molten state and creates permanent solder joints, while curing can be performed to provide drying and/or sintering as desired. Singulation 35 can thereafter occur to provide a component A 36, which is depicted at the right-hand side of FIG. 2A.

The method continues by solder paste printing 41 the second power regulation circuit board 2b and performing a component mount 42 to mount the second power regulation circuit board 2b on a second side of the inductor component 15 opposite the first side. Thereafter, a reflow 43, component A attach/cure 44, and singulation 45 are performed to generate a component B 46, which is depicted at the right-hand side of FIG. 2B.

With reference to FIG. 2C, the method continues by solder paste printing 51 the main circuit board 1, glue jetting 52 the main circuit board 1, and performing a component mount 53 to mount the component B 46 to the main circuit board 1. A solder dispensing 54 and reflow 55 can thereafter be performed to provide electrical connections between component B 46 and the main circuit board 1 to thereby form the completed power module 30. After soldering, a final vision inspection (FVI) 57 can be performed using an automated vision inspection system, and thereafter the power module 30 can be shipped to test 58.

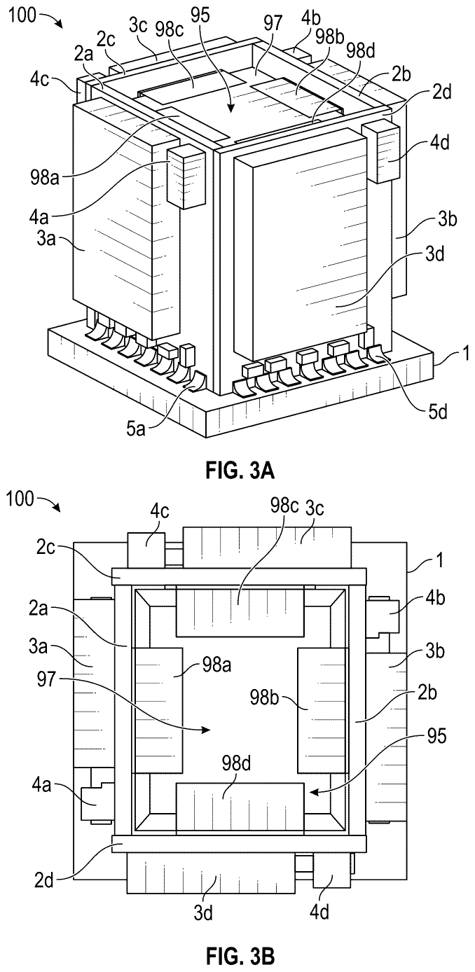

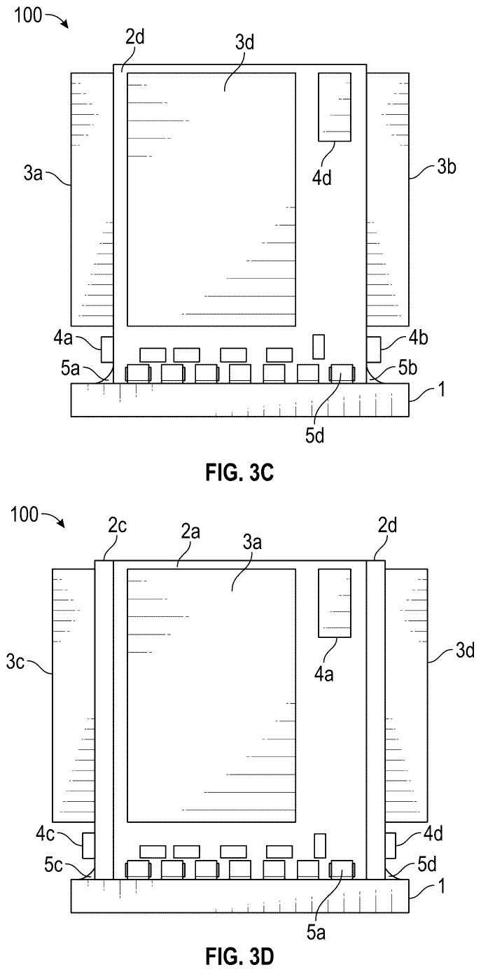

FIG. 3A is a front perspective view of a power module 100 according to another embodiment. FIG. 3B is a plan view of the power module 100 of FIG. 3A. FIG. 3C is a front view of the power module 100 of FIG. 3A. FIG. 3D is a left side view of the power module 100 of FIG. 3A.

With reference to FIGS. 3A-3D, the power module 100 includes a main circuit board 1, an inductor component 95, a first power regulation circuit board 2a, a second power regulation circuit board 2b, a third power regulation circuit board 2c, and a fourth power regulation circuit board 2d. A bottom surface of the inductor component 95 is attached to a top surface of the main circuit board 1, while each of the power regulation circuit boards 2a-2d are attached to a different side surface of the inductor component 95. The inductor component 95 includes a dielectric body 97 (for example, a ferrite core), a first inductor 98a, a second inductor 98b, a third inductor 98c, and a fourth inductor 98d.

The power module 100 of FIGS. 3A-3D is similar to the power module 30 of FIGS. 1A-1D, except that the power module 100 of FIGS. 3A-3D includes four power regulation circuit boards and corresponding to components to provide a four-phase power module.

For example, a first DrMOS die 3a and first components 4a are attached to the first power regulation circuit board 2a, and the first DrMOS die 3a operates to regulate a current through the first inductor 98a. Additionally, a second DrMOS die 3b and second components 4b are attached to the second power regulation circuit board 2b, and the second DrMOS die 3b operates to regulate a current through the second inductor 98b. Furthermore, a third DrMOS die 3c and third components 4c are attached to the third power regulation circuit board 2c, and the third DrMOS die 3c operates to regulate a current through the third inductor 98c. Additionally, a fourth DrMOS die 3d and fourth components 4d are attached to the fourth power regulation circuit board 2d, and the fourth DrMOS die 3d operates to regulate a current through the fourth inductor 98d. The main circuit board 1 includes first electrical connectors 5a for providing electrical connections to the first power regulation circuit board 2a, second electrical connectors 5b for providing electrical connections to the second power regulation circuit board 2b, third electrical connectors 5c for providing electrical connections to the third power regulation circuit board 2c, and fourth electrical connectors 5d for providing electrical connections to the fourth power regulation circuit board 2d.

In the illustrated embodiment, the power regulation circuit boards 2a-2d are each attached at an angle of about 90° relative to the top surface of the main circuit board 1. By implementing the power regulation circuit boards 2a-2d in this manner, a compact form factor is achieved.

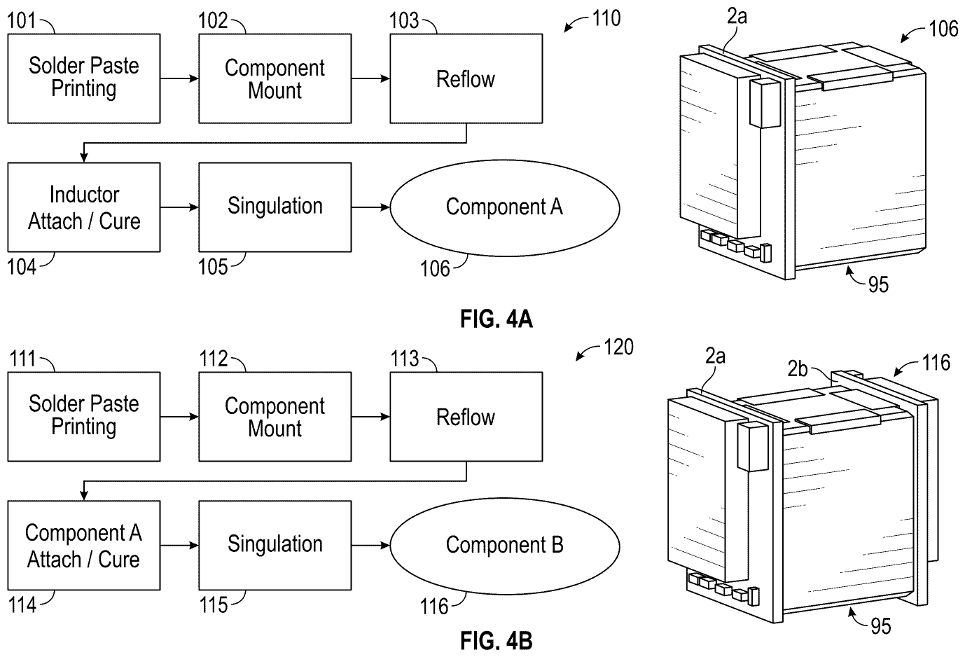

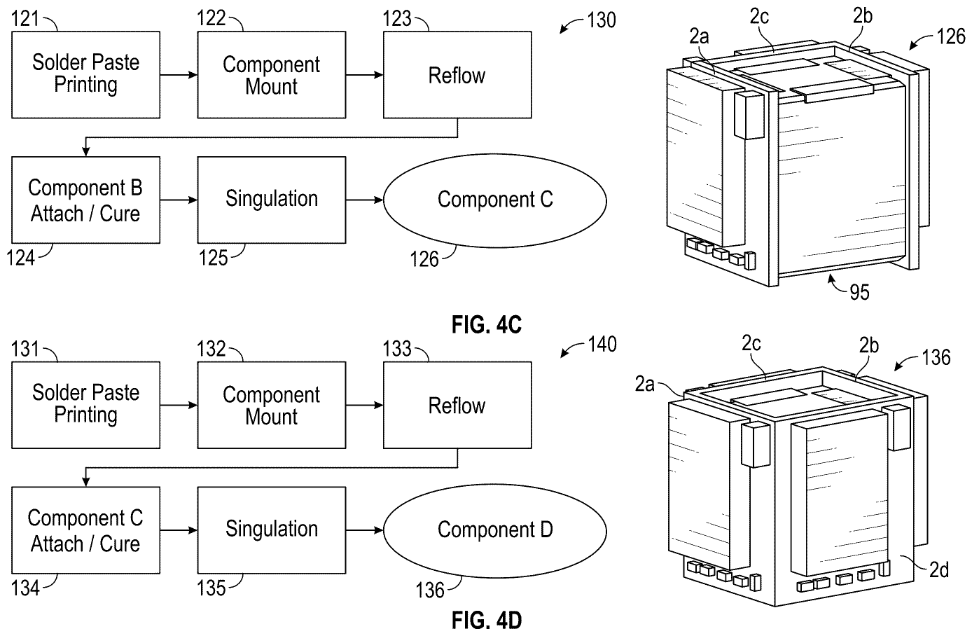

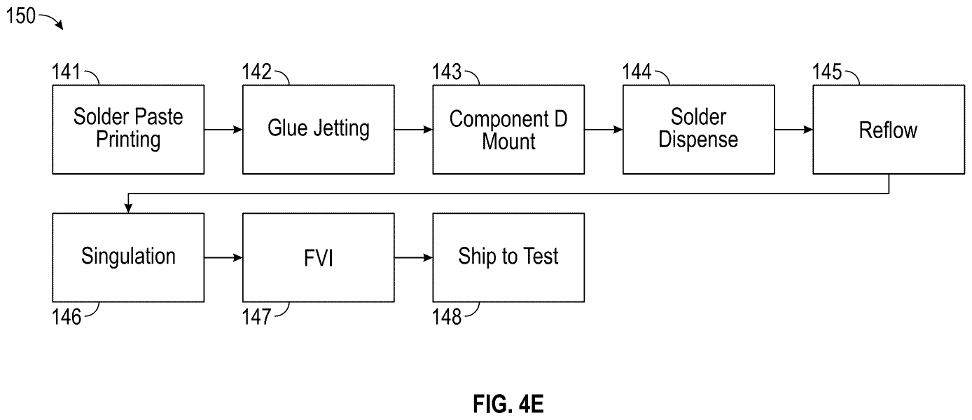

FIG. 4A is a first portion 110 of a method of assembling the power module 100 of FIGS. 3A-3D according to one embodiment. FIG. 4B depicts a second portion 120 of the method, FIG. 4C depicts a third portion 130 of the method, FIG. 4D depicts a fourth portion 140 of the method, and FIG. 4E depicts a fifth portion 150 of the method.

Although one embodiment of assembling the power module 100 is shown, the power module 100 can be assembled in other ways. Accordingly, other implementations are possible.

With reference to FIGS. 4A-4E, the method begins by solder paste printing 101 the first power regulation circuit board 2a and performing a component mount 102 to mount the first power regulation circuit board 2a on a left side of the inductor component 95. Thereafter, a reflow 103, inductor attach/cure 104, and singulation 105 are performed to generate a component A 106, which is depicted at the right-hand side of FIG. 4A.

The method continues by solder paste printing 111 the second power regulation circuit board 2b and performing a component mount 112 to mount the second power regulation circuit board 2b on a right side of the inductor component 95 opposite the left side. Thereafter, a reflow 113, component A attach/cure 114, and singulation 115 are performed to generate a component B 116, which is depicted at the right-hand side of FIG. 4B.

With reference to FIG. 4C, the method continues by solder paste printing 121 the third power regulation circuit board 2c and performing a component mount 122 to mount the third power regulation circuit board 2b on a back side of the inductor component 95. Thereafter, a reflow 123, component B attach/cure 124, and singulation 125 are performed to generate a component C 126, which is depicted at the right-hand side of FIG. 4C.

The method continues by solder paste printing 131 the fourth power regulation circuit board 2d and performing a component mount 132 to mount the fourth power regulation circuit board 2d on a front side of the inductor component 95 opposite the back side. Thereafter, a reflow 133, component C attach/cure 134, and singulation 135 are performed to generate a component D 136, which is depicted at the right-hand side of FIG. 4D.

With reference to FIG. 4E, the method continues by solder paste printing 141 the main circuit board 1, glue jetting 142 the main circuit board 1, and performing a component mount 143 to mount the component D 136 to the main circuit board 1. A solder dispensing 144 and reflow 145 can thereafter be performed to provide electrical connections between component D 136 and the main circuit board 1 to thereby form the completed power module 100. After soldering, an FVI 147 can be performed using an automated vision inspection system, and thereafter the power module 100 can be shipped to test 148.

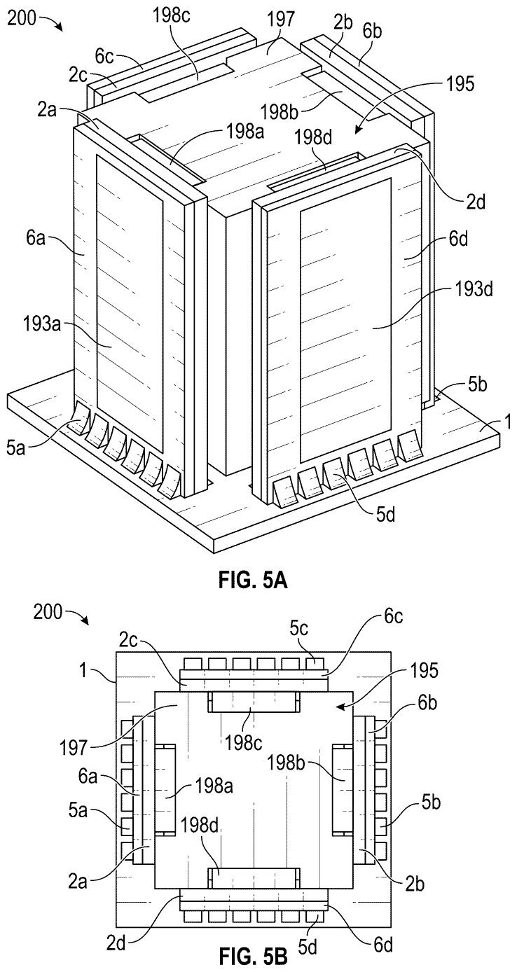

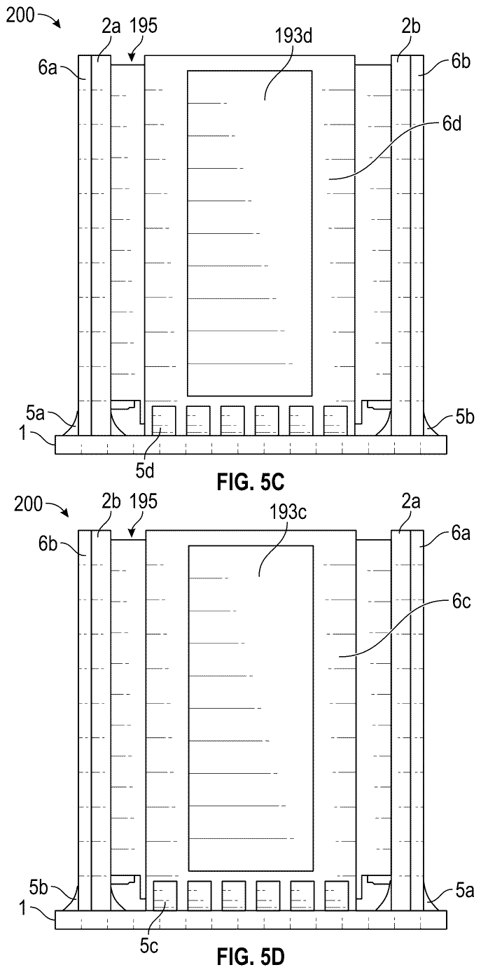

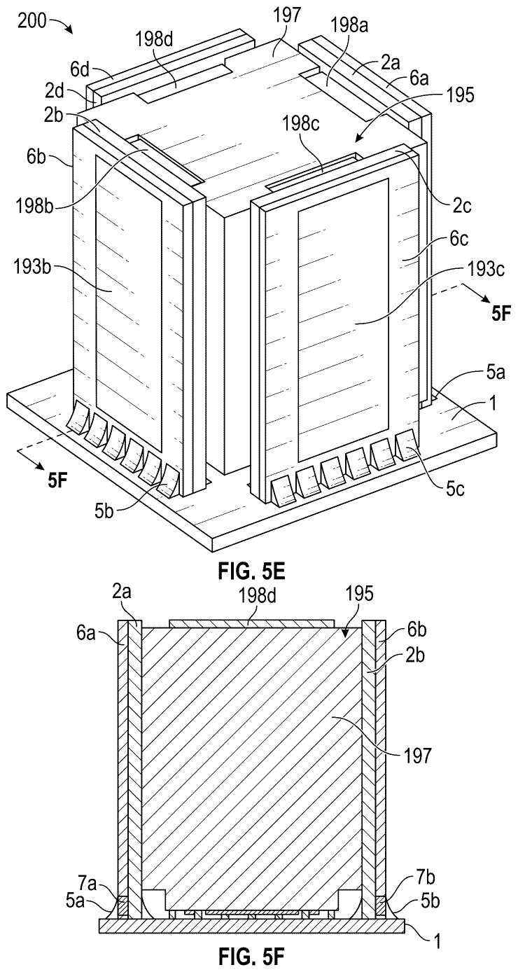

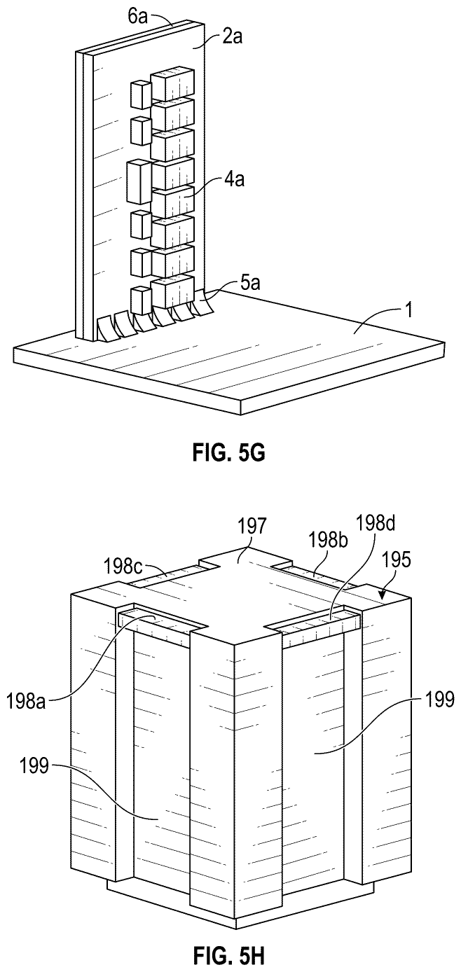

FIG. 5A is a front perspective view of a power module 200 according to another embodiment. FIG. 5B is a plan view of the power module 200 of FIG. 5A. FIG. 5C is a front view of the power module 200 of FIG. 5A. FIG. 5D is a rear view of the power module 200 of FIG. 5A. FIG. 5E is a rear perspective view of the power module 200 of FIG. 5A. FIG. 5F is a cross-section of the power module 200 of FIG. 5A taken along the line 5F-5F.

With reference to FIGS. 5A-5F, the power module 200 includes a main circuit board 1, an inductor component 195, a first power regulation circuit board 2a, a second power regulation circuit board 2b, a third power regulation circuit board 2c, and a fourth power regulation circuit board 2d. A bottom surface of the inductor component 195 is attached to a top surface of the main circuit board 1, while each of the power regulation circuit boards 2a-2d are attached to a different side surface of the inductor component 195. The inductor component 195 includes a dielectric body 197 (for example, a ferrite core), a first inductor 198a, a second inductor 198b, a third inductor 198c, and a fourth inductor 198d.

The power module 200 of FIGS. 5A-5F is similar to the power module 100 of FIGS. 3A-3D, except that the power module 200 of FIGS. 5A-5F includes DrMOS die that are attached by flip-chip to each power regulation circuit board and thereafter encapsulated. Furthermore, the DrMOS die and surface mount components are attached to opposite sides of each power regulation circuit board, in this embodiment.

For example, a first flip-chip DrMOS die 193a is attached to the first power regulation circuit board 2a and encapsulated using mold compound 6a. Additionally, a second flip-chip DrMOS die 193b is attached to the second power regulation circuit board 2b and encapsulated using mold compound 6b. Furthermore, a third flip-chip DrMOS die 193c is attached to the third power regulation circuit board 2c and encapsulated using mold compound 6c. Additionally, a fourth flip-chip DrMOS die 193d is attached to the fourth power regulation circuit board 2d and encapsulated using mold compound 6d. In the illustrated embodiment, the mold compound for each DrMOS die has been grinded to expose a portion of each DrMOS die for improved thermal performance.

Each power regulation circuit board includes conductors for electrically connecting to corresponding electrical connectors on the main circuit board 1. For example, as shown in FIG. 5F, conductor 7a (for instance, a copper slug) for the first power regulation circuit board 2a electrically connects to first electrical connector 5a of the main circuit board 1, while conductor 7b (for instance, a copper slug) for the second power regulation circuit board 2b electrically connects to second electrical connector 5b of the main circuit board 1.

In the illustrated embodiment, the DrMOS die and surface mount components are attached to opposite sides of each power regulation circuit board. For example, as shown in FIG. 5G, the first power regulation circuit board 2a includes components 4a on an inner side that faces the inductor component 195. Furthermore, as shown in FIG. 5H, recesses 199 are formed along the sides of the dielectric body 197 to provide clearance for the components of each power regulation circuit board.

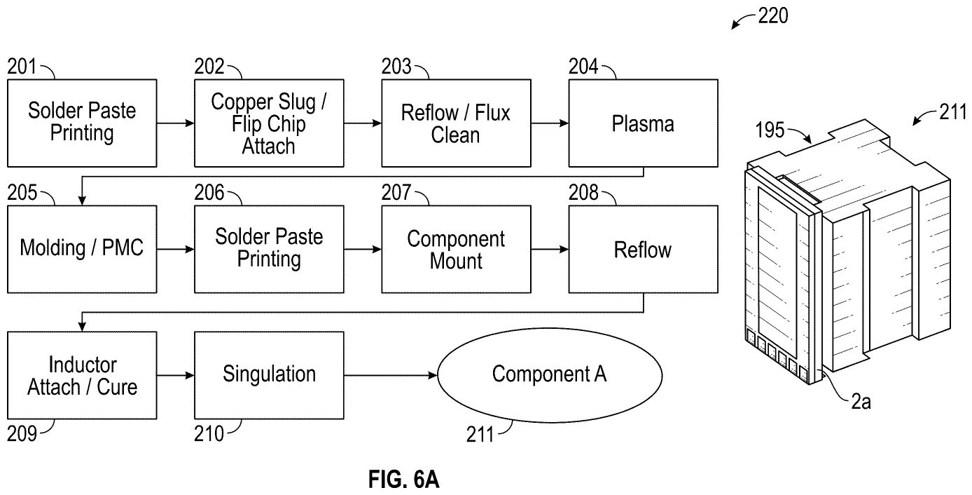

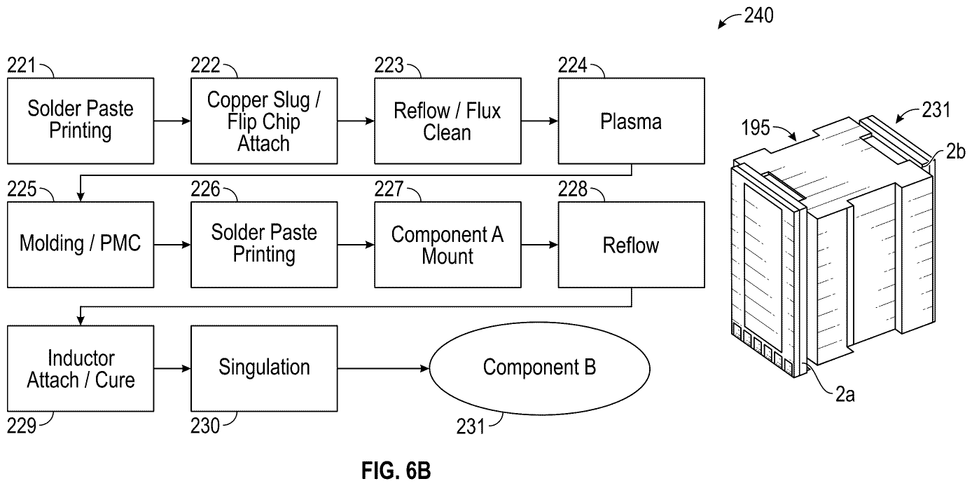

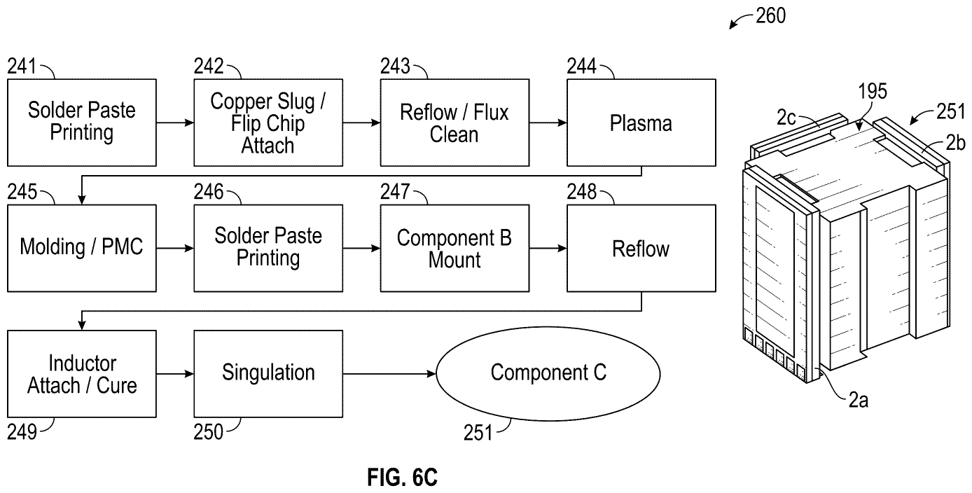

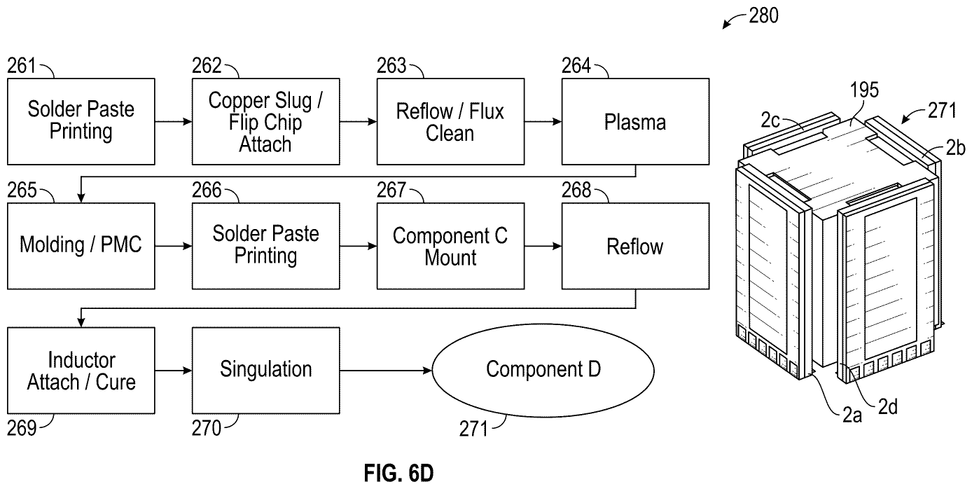

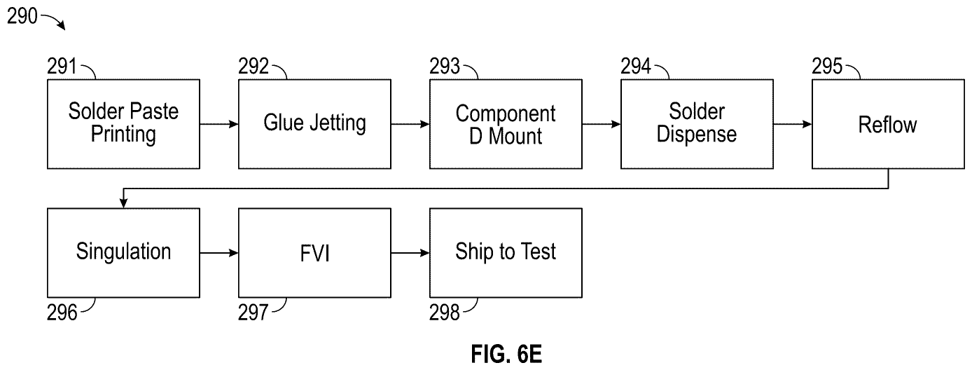

FIG. 6A is a first portion 220 of a method of assembling the power module 200 of FIGS. 5A-5F according to one embodiment. FIG. 6B depicts a second portion 240 of the method, FIG. 6C depicts a third portion 260 of the method, FIG. 6D depicts a fourth portion 280 of the method, and FIG. 6E depicts a fifth portion 290 of the method.

Although one embodiment of assembling the power module 200 is shown, the power module 200 can be assembled in other ways. Accordingly, other implementations are possible.

With reference to FIGS. 6A-6E, the method begins by solder paste printing 201 the first power regulation circuit board 2a, performing a copper slug/flip chip attach 202, performing a reflow/flux cleaning 203, processing with plasma 204, and performing a molding/post molding cure (PMC) 205 to form a completed first power regulation circuit board 2a on which the DrMOS die is encapsulated. The method continues by solder paste printing 206 the first power regulation circuit board 2a and performing a component mount 207 to mount the first power regulation circuit board 2a on a left side of the inductor component 195. Thereafter, a reflow 208, inductor attach/cure 209, and singulation 210 are performed to generate a component A 211, which is depicted at the right-hand side of FIG. 6A.

The method continues by solder paste printing 221 the second power regulation circuit board 2b, performing a copper slug/flip chip attach 222, performing a reflow/flux cleaning 223, processing with plasma 224, and performing a molding/PMC 225 to complete the second power regulation circuit board 2b. The method continues by solder paste printing 226 the second power regulation circuit board 2b and performing a component mount 227 to mount the second power regulation circuit board 2b on a right side of the component A 211. Thereafter, a reflow 228, inductor attach/cure 229, and singulation 230 are performed to generate a component B 231, which is depicted at the right-hand side of FIG. 6B.

With reference to FIG. 6C, the method continues by solder paste printing 241 the third power regulation circuit board 2c, performing a copper slug/flip chip attach 242, performing a reflow/flux cleaning 243, processing with plasma 244, and performing a molding/PMC 245 to complete the third power regulation circuit board 2c. The method continues by solder paste printing 246 the third power regulation circuit board 2c and performing a component mount 247 to mount the third power regulation circuit board 2c on a back side of the component B 231. Thereafter, a reflow 248, inductor attach/cure 249, and singulation 250 are performed to generate a component C 251, which is depicted at the right-hand side of FIG. 6C.

The method continues by solder paste printing 261 the fourth power regulation circuit board 2d, performing a copper slug/flip chip attach 262, performing a reflow/flux cleaning 263, processing with plasma 264, and performing a molding/PMC 265 to complete the fourth power regulation circuit board 2d. The method continues by solder paste printing 266 the fourth power regulation circuit board 2d and performing a component mount 267 to mount the fourth power regulation circuit board 2d on a front side of the component C 251. Thereafter, a reflow 268, inductor attach/cure 269, and singulation 270 are performed to generate a component D 271, which is depicted at the right-hand side of FIG. 6D.

With reference to FIG. 6E, the method continues by solder paste printing 291 the main circuit board 1, glue jetting 292 the main circuit board 1, and performing a component mount 293 to mount the component D 271 to the main circuit board 1. A solder dispensing 294 and reflow 295 can thereafter be performed to provide electrical connections between component D 271 and the main circuit board 1 to thereby form the completed power module 200. After soldering, an FVI 297 can be performed using an automated vision inspection system, and thereafter the power module 200 can be shipped to test 298.

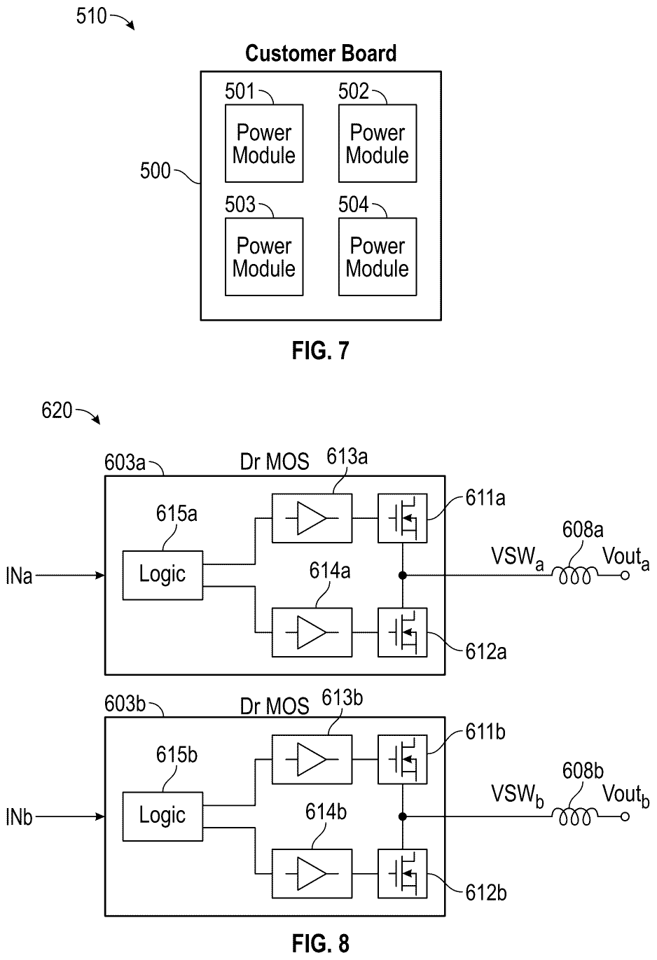

FIG. 7 is a plan view of a power regulation system 510 according to one embodiment. The power regulation system 510 includes a customer circuit board 500, a first power module 501, a second power module 502, a third power module 503, and a fourth power module 504.

In the illustrated embodiment, the power modules 501-504 have been arranged in an array. Although an example with four power modules is depicted, more or fewer power modules can be attached to a customer circuit board. Furthermore, although the power modules are depicted in two-by-two array configuration, other configurations of attaching the power modules are possible.

By including two or more power modules on a customer circuit board, a desired number of phases for power regulation can be achieved. For example, when each of the power modules 501-504 is a four-phase power module, the power regulation system 510 can operate with sixteen phases.

FIG. 8 is a circuit diagram of a power module 620 according to one embodiment. The power module 620 includes a first DrMOS die 603a, a first inductor 608a, a second DrMOS die 603b, and a second inductor 608b. Although an example of a 2-phase power module with two DrMOS dies and two inductors is depicted, any number of DrMOS dies and corresponding inductors can be included as needed for a particular application.

In the illustrated embodiment, each DrMOS die 603a/603b includes various MOSFET power switches as well as drivers for controlling the MOSFET power switches. For example, the first DrMOS die 603a includes a high side power MOSFET 611a, a low side power MOSFET 612a, a high side driver 613a, a low side driver 614a, and a driver logic circuit 615a. Additionally, the second DrMOS die 603b includes a high side power MOSFET 611b, a low side power MOSFET 612b, a high side driver 613b, a low side driver 614b, and a driver logic circuit 615b.

Although one example of a DrMOS die is shown, DrMOS dies can be implemented in other ways. Accordingly, other implementations are possible. Furthermore, although certain components of the DrMOS dies are depicted, DrMOS dies can include additional circuitry. Moreover, various power and ground supplies as well as signals are not shown in FIG. 8 for clarity of the figure.

In the illustrated embodiment, an input control signal INa to the first DrMOS die 603a is provided to the logic 615a. The logic 615a controls driver signals to the high side driver 613a and the low side driver 614a, which control the high side power MOSFET 611a and low side power MOSFET 612a, respectively. The high side power MOSFET 611a and low side power MOSFET 612a are coupled to a first terminal VSWₐ of the inductor 608a to form a half bridge circuit of a switching regulator, such as a buck converter. The MOSFETs 612a/612b are switched on and off to control a current provided to the inductor 608a. A second terminal Voutₐ of the inductor 608a electrically connects to a load on a customer circuit board.

With continuing reference to FIG. 8, an input control signal INb to the second DrMOS die 603b is provided to the logic 615b. The logic 615b controls driver signals to the high side driver 613b and the low side driver 614b, which control the high side power MOSFET 611b and low side power MOSFET 612b, respectively. The high side power MOSFET 611b and low side power MOSFET 612b are coupled to a first terminal VSW_{b} of the inductor 608b and are switched on and off to control a current provided to the inductor 608b. A second terminal Vout_{b} of the inductor 608b electrically connects to a load on a customer circuit board.

In certain implementations, a controller die (not shown in FIG. 8), generates the input signal INa and the input signal INb according to a desired control scheme, such as pulse width modulation (PWM).

In certain embodiments herein, such a controller die is included on a power module. In one embodiment, a control circuit board is included on a top surface of an inductor component opposite a main circuit board that is attached to a bottom surface of the inductor component, and the control circuit board includes a controller die. In this embodiment, two or more power regulation circuit boards can be placed on the sides of the inductor component. Thus, in this embodiment, the two or more power regulation circuit boards can extend perpendicularly (for instance, at about 90°) from both the main circuit board and the control circuit board.

### Applications

Devices employing the above-described schemes can be implemented into various electronic devices in a wide range of applications including, but not limited to, bus converters, high current distributed power systems, telecom systems, datacom systems, storage systems, and automotive systems. Thus, examples of electronic devices that can be implemented with the power modules herein include, but are not limited to, communication systems, consumer electronic products, electronic test equipment, communication infrastructure, servers, automobiles, etc.

### Conclusion

The foregoing description may refer to elements or features as being “connected” or “coupled” together. As used herein, unless expressly stated otherwise, “connected” means that one element/feature is directly or indirectly connected to another element/feature, and not necessarily mechanically. Likewise, unless expressly stated otherwise, “coupled” means that one element/feature is directly or indirectly coupled to another element/feature, and not necessarily mechanically. Thus, although the various schematics shown in the figures depict example arrangements of elements and components, additional intervening elements, devices, features, or components may be present in an actual embodiment (assuming that the functionality of the depicted circuits is not adversely affected).

While certain embodiments have been described, these embodiments have been presented by way of example only and are not intended to limit the scope of the disclosure. Indeed, the novel apparatus, methods, and systems described herein may be embodied in a variety of other forms; furthermore, various omissions, substitutions, and changes in the form of the methods and systems described herein may be made without departing from the spirit of the disclosure. For example, while the disclosed embodiments are presented in a given arrangement, alternative embodiments may perform similar functionalities with different components and/or circuit topologies, and some elements may be deleted, moved, added, subdivided, combined, and/or modified. Each of these elements may be implemented in a variety of different ways. Any suitable combination of the elements and acts of the various embodiments described above can be combined to provide further embodiments. Accordingly, the scope of the present invention is defined only by reference to the appended claims.

Although the claims presented here are in single dependency format for filing at the USPTO, it is to be understood that any claim may depend on any preceding claim of the same type except when that is clearly not technically feasible.

What is claimed is:

1. A power module comprising:
a main circuit board;
an inductor component attached to the main circuit board, wherein the inductor component includes two or more inductors formed in a dielectric body; and
two or more power regulation circuit boards each attached to a different side of the inductor component, wherein each power regulation circuit board includes a semiconductor die operable to regulate a current through a corresponding inductor of the two or more inductors.

2. The power module of claim 1 wherein each of the two or more power regulation circuit boards extends substantially perpendicular to the main circuit board.

3. The power module of claim 1 wherein the two or more power regulation circuit boards include a first power regulation circuit board attached to a first side of the inductor component and a second power regulation circuit board attached to a second side of the inductor component opposite the first side.

4. The power module of claim 3 wherein the two or more power regulation circuit boards further include a third power regulation circuit board attached to a third side of the inductor component and a fourth power regulation circuit board attached to a fourth side of the inductor component opposite the third side.

5. The power module of claim 3 wherein a first semiconductor die of the first power regulation circuit board includes a first output electrically connected to a first end of a first inductor of the two or more inductors, and wherein a second semiconductor die of the second power regulation circuit board includes a second output electrically connected to a first end of a second inductor of the two or more inductors.

6. The power module of claim 5 wherein a second end of the first inductor and a second end of the second inductor are electrically connected to corresponding terminals of the main circuit board.

7. The power module of claim 1 wherein the semiconductor die is attached to a first side of the power regulation circuit board opposite the inductor component.

8. The power module of claim 7 wherein the semiconductor die is packaged, the first side of the power regulation circuit board further including one or more surface mount components.

9. The power module of claim 7 wherein the semiconductor die is flip chip attached to the first side of the power regulation circuit board and encapsulated in a mold compound.

10. The power module of claim 9 wherein one or more surface mount components are attached to a second side of the power regulation circuit board opposite the first side, the dielectric body of the inductor component including a recess for providing clearance for the one or more surface mount components.

11. The power module of claim 9 wherein the mold compound is grinded to expose a portion of the semiconductor die.

12. The power module of claim 1 wherein an edge of each power regulation circuit board is attached to the main circuit board, and the main circuit board includes a plurality of electrical connectors providing a plurality of electrical connections between the main circuit board and the two or more power regulation circuit boards.

13. The power module of claim 1 wherein each semiconductor die includes a high side metal-oxide-semiconductor field-effect transistor (MOSFET) switch electrically connected to a regulator output, a high side driver configured to control the high side MOSFET switch, a low side MOSFET switch electrically connected to the regulator output, and a low side driver configured to control the low side MOSFET switch.

14. The power module of claim 1 wherein the dielectric body includes a ferrite core.

15. A power regulation system comprising:
a customer circuit board; and
a first power module attached to the customer circuit board, the first power module comprising:
a main circuit board;
an inductor component attached to the main circuit board, wherein the inductor component includes two or more inductors formed in a dielectric body; and
two or more power regulation circuit boards each attached to a different side of the inductor component, wherein each power regulation circuit board includes a semiconductor die operable to regulate a current through a corresponding inductor of the two or more inductors.

16. The power regulation system of claim 15 comprising at least one additional power module attached to the customer circuit board and configured to operate in combination with the first power module to provide multi-phase power regulation with 8 or more phases.

17. A method of power module assembly, the method comprising:
attaching a first power regulation circuit board to a first side of an inductor component, wherein the inductor component includes a first inductor and a second inductor formed in a dielectric body;
electrically connecting a first semiconductor die on the first power regulation circuit board to the first inductor;
attaching a second power regulation circuit board to a second side of the inductor component;
electrically connecting a second semiconductor die on the second power regulation circuit board to the second inductor; and
attaching the inductor component including the first power regulation circuit board and the second power regulation circuit board to a main circuit board to form a power module.

18. The method of claim 17 wherein the first power regulation circuit board and the second power regulation circuit board each extend substantially perpendicular to the main circuit board in the power module.

19. The method of claim 17 further comprising attaching a third power regulation circuit board to a third side of the inductor component and attaching a fourth power regulation circuit board to a fourth side of the inductor component.

20. The method of claim 17 further comprising attaching the first semiconductor die the first power regulation circuit board in a flip-chip configuration, and encapsulating the first semiconductor die in a mold compound.
